(19) United States
(12) Patent Application Publication
(10) Pub. No.: US 2015/0103482 A1
(43) Pub. Date: Apr. 16, 2015

(54) HARD DISK DRIVE MOUNTING DEVICE AND INFORMATION PROCESSING APPARATUS

(71) Applicant: FUJITSU LIMITED, Kawasaki-shi (JP)

(72) Inventor: TAKASHI SAITO, Kawasaki (JP)

(21) Appl. No.: 14/508,064

(22) Filed: Oct. 7, 2014

(30) Foreign Application Priority Data
Oct. 10, 2013 (JP) 2013-212888

(51) Int. Cl. H05K 7/14; H05K 5/02

(52) U.S. Cl. CPC H05K 7/1489; H05K 5/0204
USPC 361/679.39

(57) ABSTRACT

A hard disk drive mounting device includes: a housing; a mounting area provided in the housing and configured to mount a plurality of hard disk drives; a first hard disk drive provided with a guide pin protruding on both side surfaces thereof; and a mechanism configured to attach the first hard disk drive to the mounting area, and configured to detach the first hard disk drive from the mounting area, the mechanism including: a fixed rail including a guiding groove configured to receive the guide pin, and a moving rail positioned adjacent to the fixed rail and configured to move the guide pin inserted into the guiding groove by a driving groove, wherein, when the moving rail moves to one end of the fixed rail in a state where the guide pin is inserted into the guiding groove, the first hard disk drive is mounted in a mounting part.

### CROSS-REFERENCE TO RELATED APPLICATION

This application is based upon and claims the benefit of priority of the prior Japanese Patent Application No. 2013-212888 filed on Oct. 10, 2013, the entire contents of which are incorporated herein by reference.

### FIELD

The embodiments discussed herein are related to a hard disk drive mounting device and an information processing apparatus into which the hard disk drive mounting device is inserted.

### BACKGROUND

I
[Document 1] Japanese National Publication of International Patent Application No. 2002-503376

### SUMMARY

According to an aspect of the invention, a hard disk drive mounting device includes: a housing; a mounting area provided in the housing and configured to mount a plurality of hard disk drives; a first hard disk drive provided with a guide pin protruding on both side surfaces thereof; and a mechanism configured to attach the first hard disk drive to the mounting area, and configured to detach the first hard disk drive from the mounting area, the mechanism including: a fixed rail including a guiding groove configured to receive the guide pin, and a moving rail positioned adjacent to the fixed rail and configured to move the guide pin inserted into the guiding groove by a driving groove, wherein, when the moving rail moves to one end of the fixed rail in a state where the guide pin is inserted into the guiding groove, the first hard disk drive is mounted in a mounting part, and when the moving rail moves to the other end of the fixed rail in a state where the first hard disk drive is mounted in the mounting part, the hard disk drive is ejected from the mounting part.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a partial perspective view illustrating a structure of a server mounting rack, in which a plurality of rack mount server devices is mounted, in a related art;

FIG. 1B is a perspective view illustrating one rack mount server device which is ejected from the server mounting rack illustrated in FIG. 1A and a hard disk drive which is ejected from a hard disk mounting unit of the rack mount server device;

FIG. 2A is a partial plan view illustrating a state where one hard disk drive is ejected from a front cell of the rack mount server device illustrated in FIG. 1B;

FIG. 2B is a side view of FIG. 2A;

FIG. 3A is a partial plan view illustrating an extension/maintenance working area of a hard disk drive in the one rack mount server device which is ejected from the server mounting rack illustrated in FIG. 1A;

FIG. 3B is an explanatory view illustrating an operation of removing or inserting one hard disk drive, which is ejected from or inserted into the rack mount server device illustrated in FIG. 3A, from or into the extension/maintenance working area;

FIG. 4A is a partial plan view illustrating a connection structure which connects the hard disk drive and a connector at a rack side in a hard disk mounting unit of the rack mount server device illustrated in FIG. 1B, in another related art;

FIG. 4B is a side view illustrating a state where the hard disk drive is ejected from the extension/maintenance working area of the hard disk drive illustrated in FIG. 4A in a vertical direction;

FIG. 5A is a plan view illustrating a state where cooling air flows in a hard disk mounting unit of the rack mount server device illustrated in FIG. 4A;

FIG. 5B is a side view illustrating a state where cooling air flows in a hard disk unit illustrated in FIG. 5A;

FIG. 6A is a side view of a rack mount server device illustrating an unused area in the rack mount server device illustrated in FIG. 1B;

FIG. 6B is a side view illustrating a state where a cooling duct is provided in the unused area illustrated in FIG. 6A;

FIG. 7A is a perspective view illustrating a structure of a hard disk drive which is mounted in the rack mount server device of the present disclosure;

FIG. 7B is a perspective view illustrating a state where one hard disk drive is ejected from the rack mount server device according to a first embodiment of the present disclosure;

FIG. 8A is an assembly perspective view illustrating a structure of one hard disk drive attaching/detaching mechanism which is provided in the rack mount server device according to the first embodiment of the present disclosure illustrated in FIG. 7B;

FIG. 8B is a partial perspective view illustrating a structure of one hard disk drive attaching/detaching mechanism which does not have a hard disk drive and is provided in the rack mount server device according to the first embodiment of the present disclosure illustrated in FIG. 7B;

FIG. 9A is an assembly perspective view illustrating a relationship between a guide pin which is provided to protrude from the hard disk drive and a fixed rail and a moving rail of the rack mount server device according to the first embodiment of the present disclosure;

FIG. 9B is a transition diagram illustrating an operation of the moving rail with respect to the fixed rail when a lever attached to the moving rail moves from an open state to a closed state;

FIG. 9C is a transition diagram illustrating an operation of the moving rail with respect to the fixed rail when a lever attached to the moving rail moves from a closed state to an open state;

FIG. 10A is a side view of a hard disk drive attaching/detaching mechanism illustrating a state where a guide pin of the hard disk drive illustrated in FIG. 9A is inserted in a guiding groove of the fixed rail of the rack mount server device in which the lever is in an open state;

FIG. 10B is a cross-sectional view of the rack mount server device illustrated in FIG. 10A, taken along the line A-A;

FIG. 10C is a side view of a hard disk drive attaching/detaching mechanism illustrating a state where a guide pin of the hard disk drive reaches a bottom of a vertical part of a guiding groove of the fixed rail, in a state illustrated in FIG. 10A;

FIG. 10D is a side view of a hard disk drive attaching/detaching mechanism illustrating a state where a guide pin of the hard disk drive moves along a horizontal part of a guiding groove of the fixed rail, in a state illustrated in FIG. 10C;

FIG. 10E is a side view of a hard disk drive attaching/detaching mechanism illustrating a state where a guide pin of the hard disk drive completely moves to an end of a horizontal part of a guiding groove of the fixed rail, in a state illustrated in FIG. 10D;

FIG. 10F is a cross-sectional view of the rack mount server device illustrated in FIG. 10E, taken along the line B-B;

FIG. 11A is a side view of a hard disk drive attaching/detaching mechanism illustrating operations of a fixed rail, a moving rail, and a guide pin of a hard disk drive when a lever is lifted in a state illustrated in FIG. 10E;

FIG. 11B is a side view of a hard disk drive attaching/detaching mechanism illustrating a state where a guide pin of a hard disk drive moves to an intersecting part of a horizontal part and a vertical part of a guiding groove of a fixed rail b/y further lifting the lever in the state illustrated in FIG. 11A;

FIG. 11C is a side view of a hard disk drive attaching/detaching mechanism illustrating a state where a guide pin of the hard disk drive moves along a vertical part of a guiding groove of the fixed rail, by further lifting a lever in a state illustrated in FIG. 11B;

FIG. 11D is a side view of a hard disk drive attaching/detaching mechanism illustrating a state where a lever is completely open by further lifting the lever in a state illustrated in FIG. 11C;

FIG. 12A is a partial plan view illustrating flow of cooling air in a rack mount server device according to the first embodiment which includes a hard disk drive attaching/detaching mechanism of the present disclosure illustrated in FIG. 7B;

FIG. 12B is a side view illustrating flow of cooling air in the rack mount server device illustrated in FIG. 12A, as viewed from a side;

FIG. 13A is a perspective view illustrating a state where a rack mount server device with a maintenance cover which is attached on the rack mount server device illustrated in FIG. 7B is mounted in the server mounting rack;

FIG. 13B is a perspective view illustrating a state where the rack mount server device illustrated in FIG. 13A is extracted from a server mounting rack and a maintenance cover is removed;

FIG. 13C is a side view of the rack mount server device illustrated in FIG. 13A as seen from a side;

FIG. 14A is a perspective view illustrating a rack mount server device of a second embodiment of the present disclosure which is mounted in a server mounting rack;

FIG. 14B is a side view of the rack mount server device illustrated in FIG. 14A when viewed from a side;

FIG. 15A is a perspective view illustrating a rack mount server device according to a modified embodiment of a second embodiment which may be mounted in a server mounting rack;

FIG. 15B is a side view illustrating a state of cooling air which flows in the rack mount server device illustrated in FIG. 15A;

FIG. 16A is a side view illustrating a hard disk drive attaching/detaching mechanism having another structure which is mounted in a rack mount server device of a first embodiment of the present disclosure;

FIG. 16B is a side view of a hard disk drive attaching/detaching mechanism illustrating states of a fixed rail, a moving rail, and a guide pin of a hard disk drive when a lever is lifted in a state illustrated in FIG. 16A;

FIG. 16C is a side view of a hard disk drive attaching/detaching mechanism illustrating states of a fixed rail, a moving rail, and a guide pin of a hard disk drive when a lever is further lifted to be completely open in a state illustrated in FIG. 16B;

FIG. 17A is a perspective view of a hard disk drive attaching/detaching mechanism having another structure which is provided in a rack mount server device of the present disclosure;

FIG. 17B is a side view of a hard disk drive attaching/detaching mechanism illustrating a state where a finger is suspended on an extracting rod of the hard disk drive attaching/detaching mechanism having another structure of the present disclosure to extract the moving rail;

FIG. 17C is a side view of a hard disk drive attaching/detaching mechanism illustrating states of a fixed rail, a moving rail, and a guide pin of a hard disk drive when an extracting rod is further extracted in a state illustrated in FIG. 17B;

FIG. 17D is a side view of a hard disk drive attaching/detaching mechanism illustrating states of a fixed rail, a moving rail, and a guide pin of a hard disk drive when an extracting rod is further extracted to a maximum extracting position in a state illustrated in FIG. 17C; and

FIG. 18 is a flowchart illustrating an exchange procedure when one hard disk drive is actively exchanged from a rack mount server device including a hard disk drive attaching/detaching mechanism of the present disclosure which is mounted in the server mounting rack by comparing with an exchange procedure in a comparative technology.

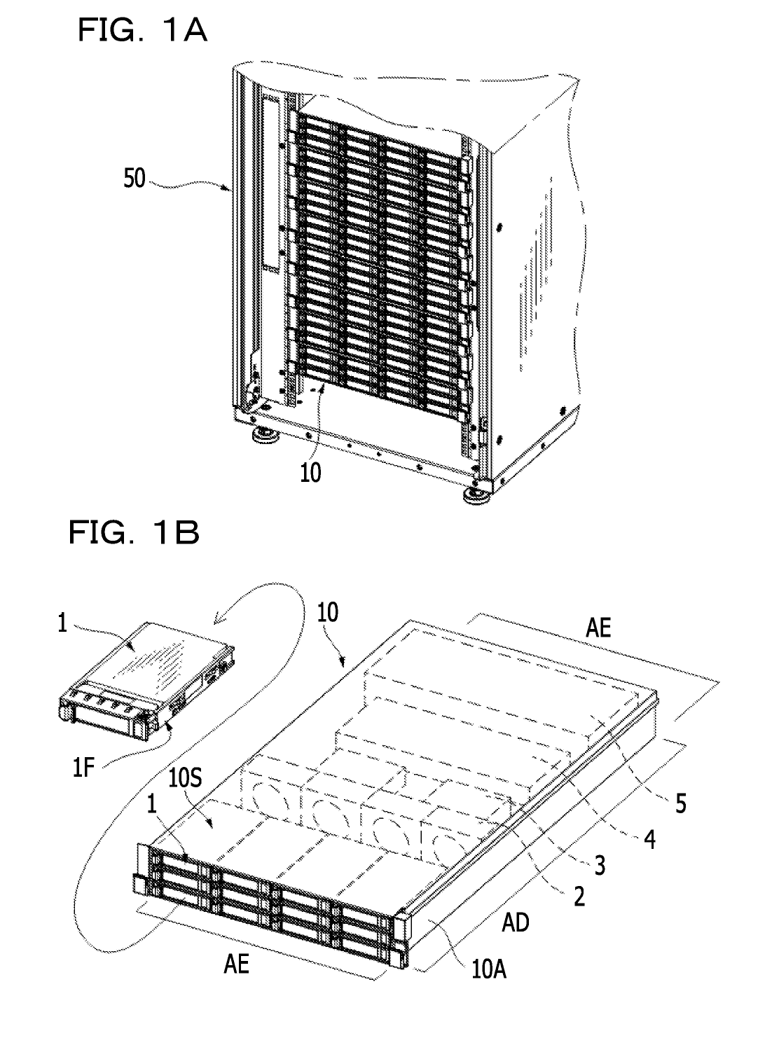

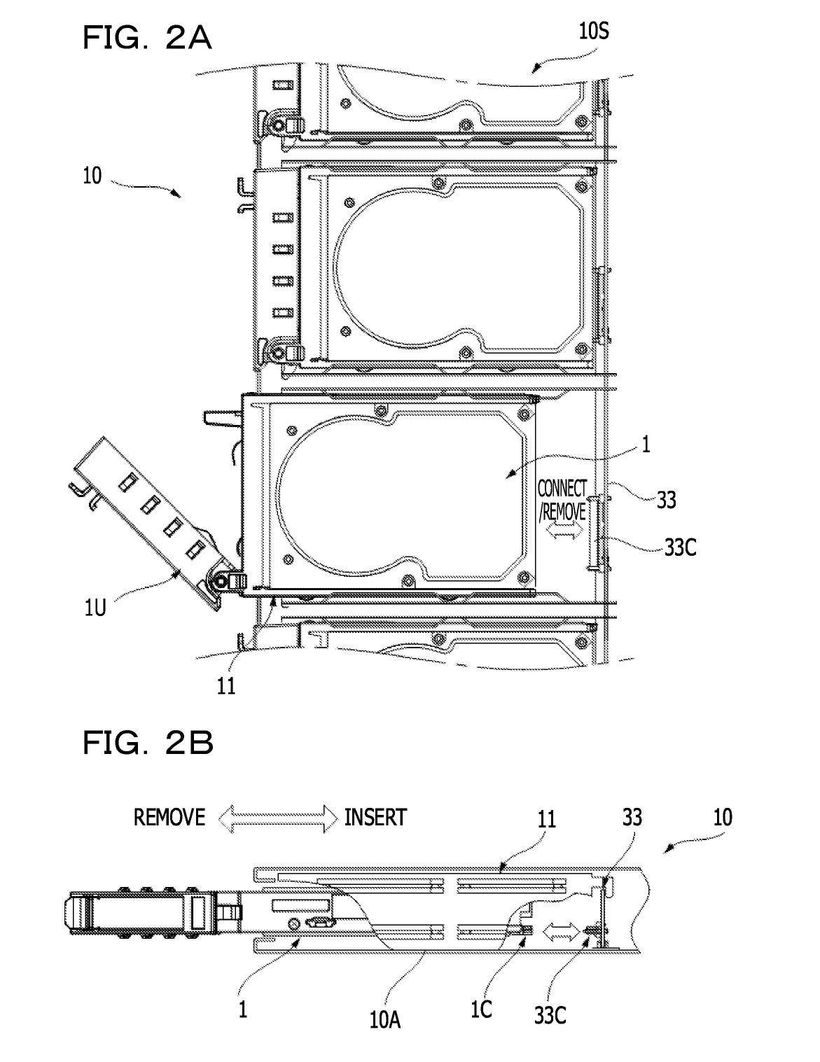

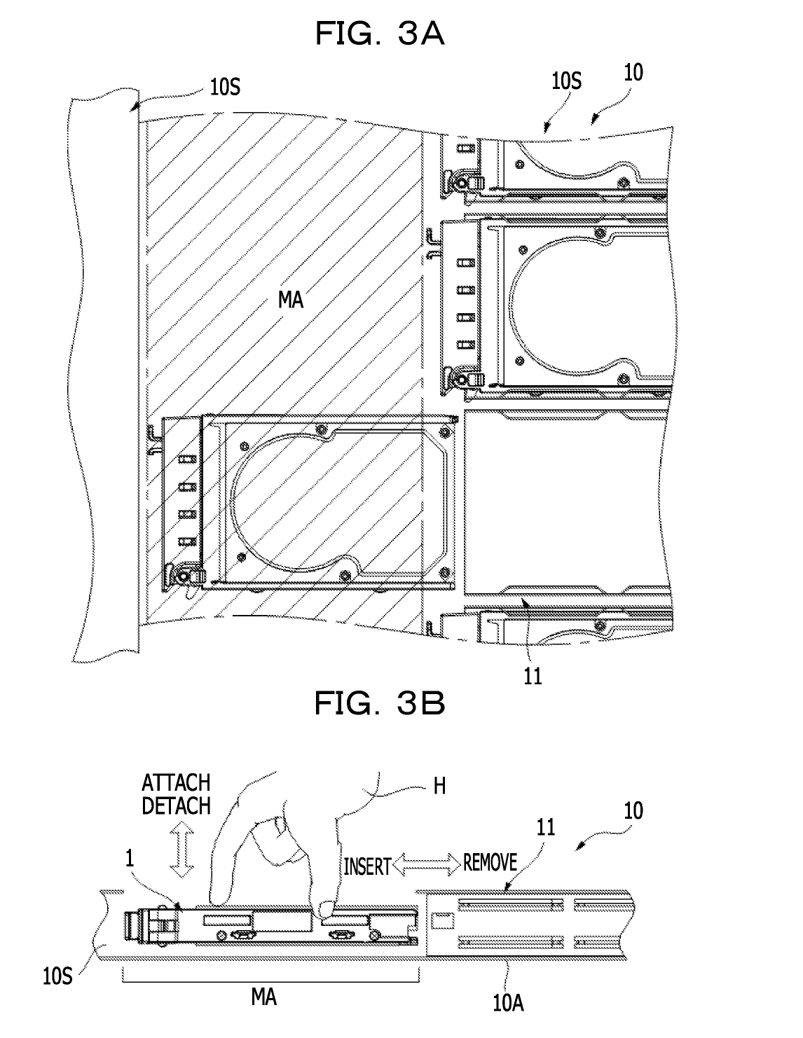

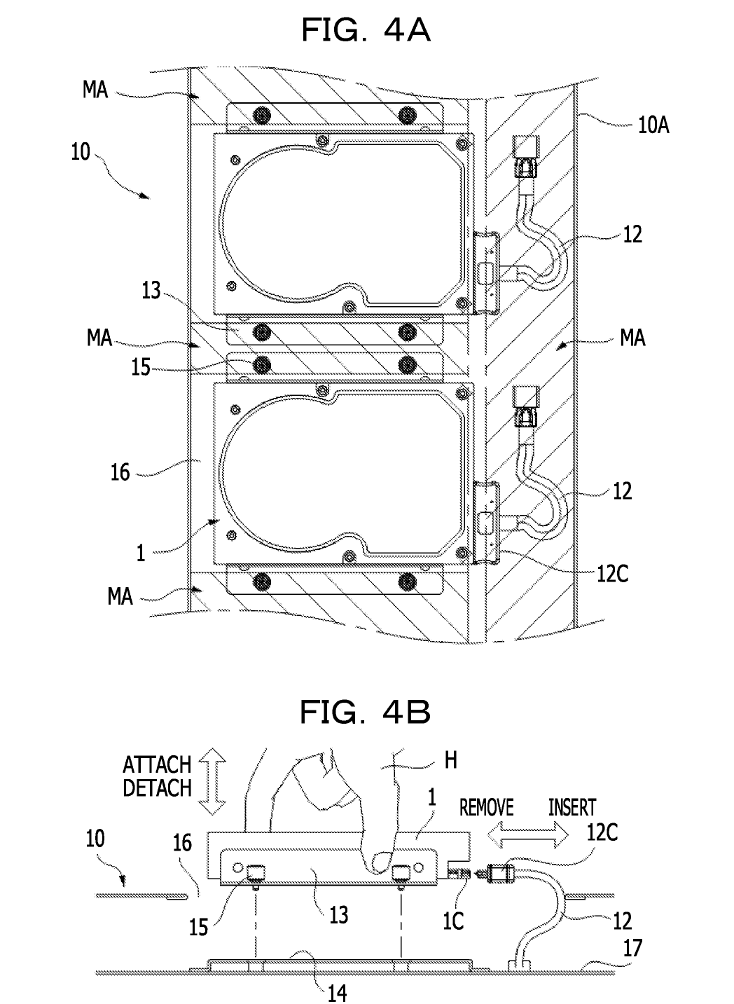

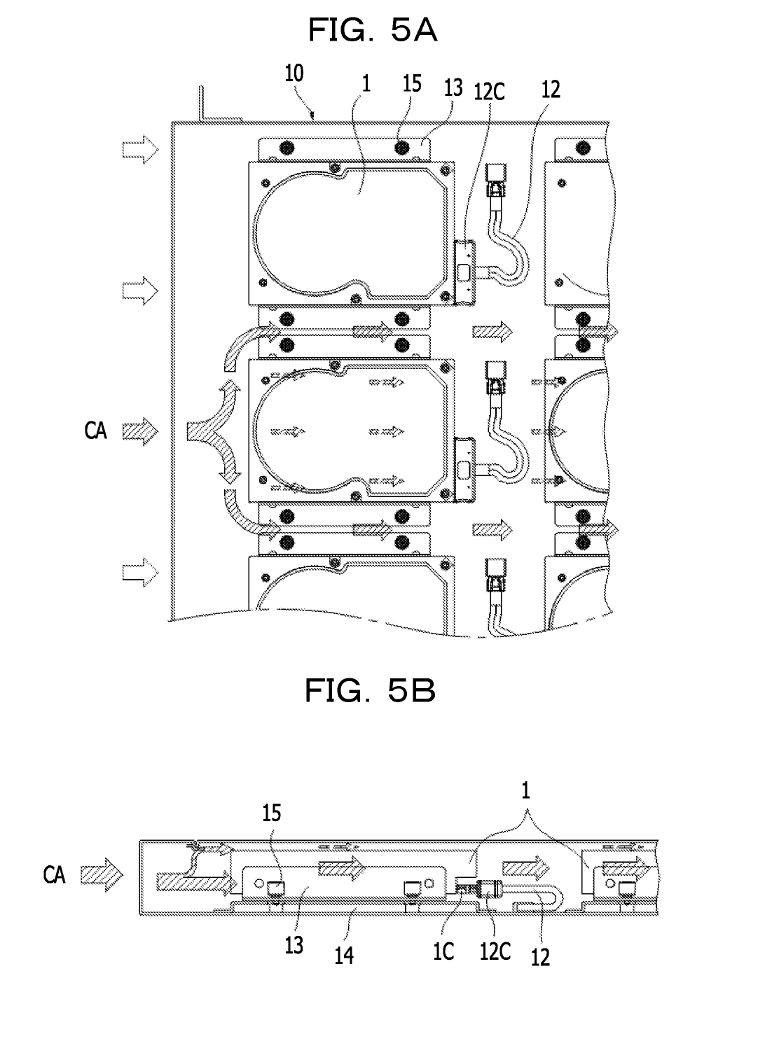

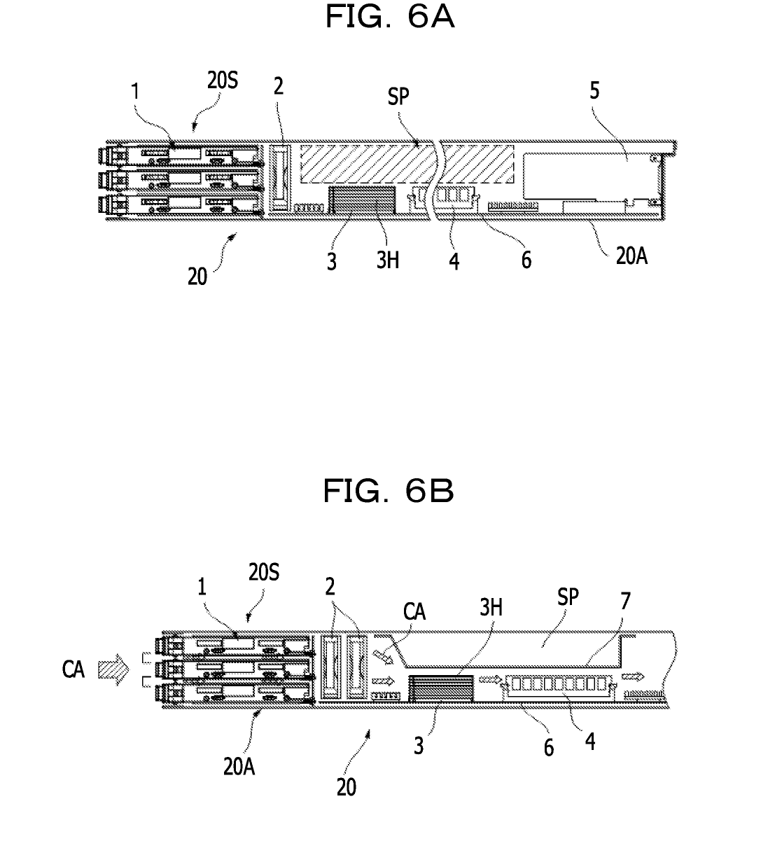

### DESCRIPTION OF EMBODIMENTS

Hereinafter, an embodiment of a hard disk drive mounting device according to the present disclosure will be described in detail based on specific embodiments with reference to accompanying drawings. In the meantime, in the embodiments which will be described below, even though a hard disk drive (HDD) is described, the present mechanism may be applied to any device shaped like the hard disk drive. For example, the mechanism may also be applicable to a solid state drive (SSD) which is called as an optical disk device or a silicon disk.

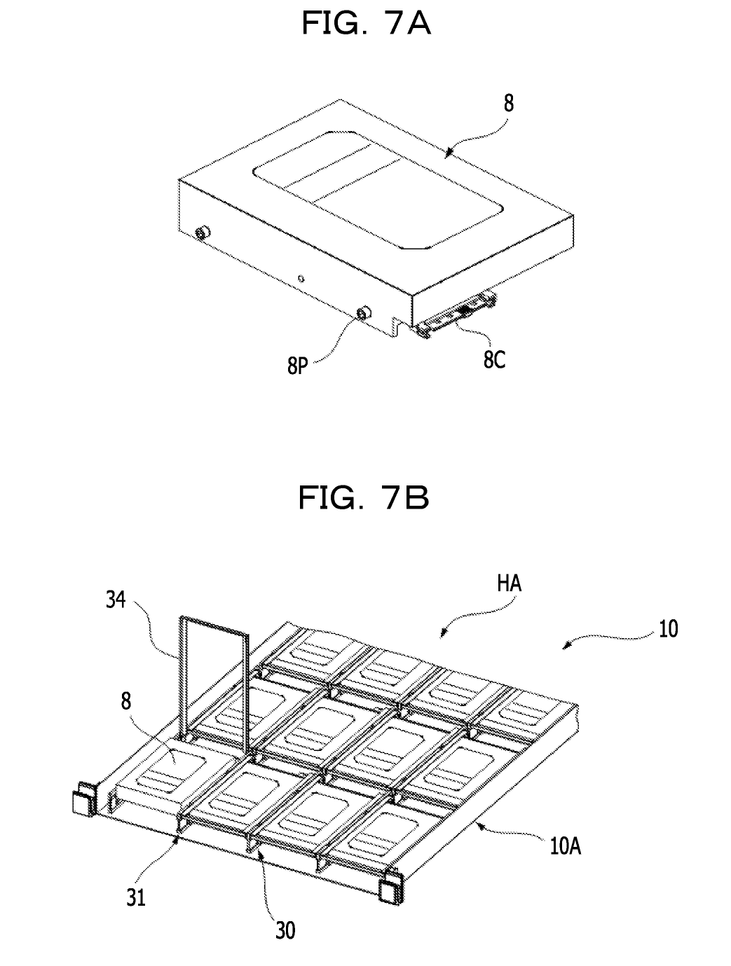

FIG. 7A illustrates a structure of a hard disk drive 8 which is mounted in a hard disk drive mounting device according to the present disclosure. The hard disk drive 8 which is mounted in the hard disk drive mounting device of the present disclosure is configured such that two guide pins 8P are provided at both sides to protrude and a connector 8C is provided at one of ends which are adjacent to the both sides.

FIG. 7B illustrates a state where one hard disk drive 8 is ejected from the rack mount server device 10 according to a first embodiment of the present disclosure, which is a hard disk drive mounting device which is extracted from a rack mount server device. A housing 10A of the rack mount server device 10 of the first embodiment has a height as high as 1 U and accommodates one hard disk drive in a height direction. The rack mount server device 10 has a mounting area HA of a hard disk drive and a plurality of hard disk drives 8 is mounted in the mounting area HA to be parallel to each other in a vertical direction and a horizontal direction. In the rack mount server device 10 of the first embodiment, hard disk drive attaching/detaching mechanisms 30 are provided as many as the hard disk drives 8 which are mounted in the rack mount server device 10. Each hard disk drive attaching/detaching mechanism 30 includes a manipulating lever 34 and when the manipulating lever 34 is lifted, the hard disk drive 8 is ejected from the mounting area HA.

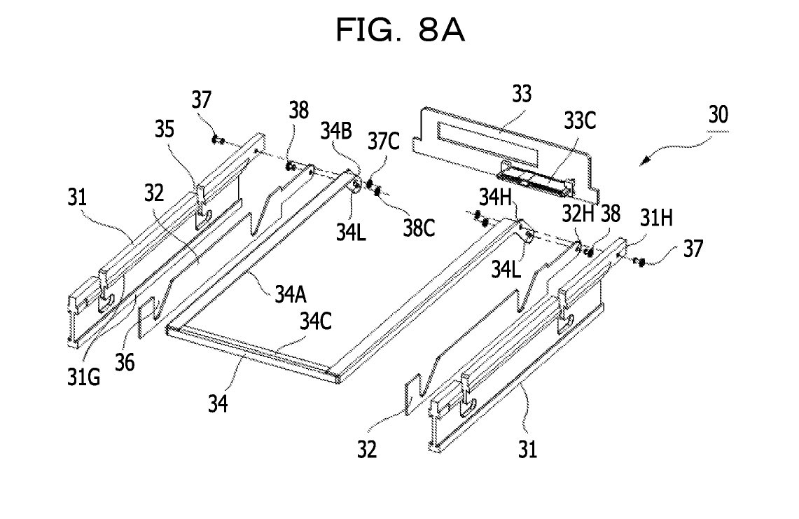

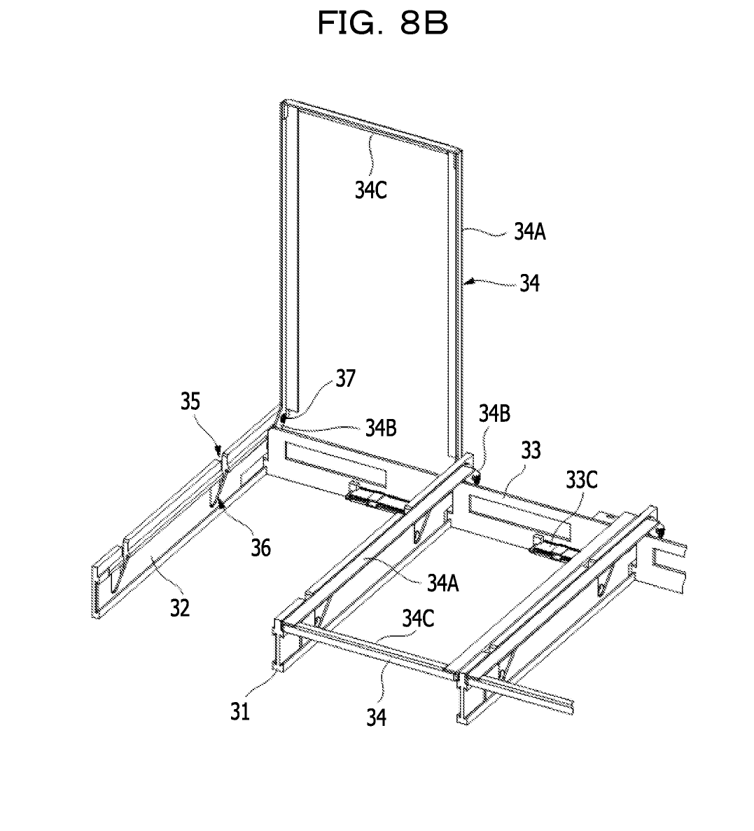

FIG. 8A illustrates a structure of one hard disk drive attaching/detaching mechanism 30 which is provided in the rack mount server device 10 according to the first embodiment of the present disclosure illustrated in FIG. 7B. The hard disk drive attaching/detaching mechanism 30 includes two fixed rails 31, two moving rails 32, a circuit board 33, and the manipulating lever 34. The two fixed rails 31 are disposed in parallel to each other and the circuit board 33 is provided between one ends of the fixed rails 31 and includes a connection connector 33C which is connected to the hard disk drive 8.

Slide guides 31G are provided at both sides of the fixed rails 31 to slide the moving rails 32. Accordingly, the moving rails 32 may slide in a space between the slide guides 31G of the fixed rails 31 in a direction away from or approaching the circuit board 33. The moving rails 32 may be provided at both sides of the fixed rails 31. Each of the two fixed rails 31 has guiding grooves 35 corresponding to the positions of guide pins 8P of the hard disk drive 8. The guiding grooves 35 include vertical grooves 35B which receive the guide pins 8P when the hard disk drive 8 is mounted and horizontal grooves 35H which move the guide pins 8P in the vertical grooves 35V toward the circuit board 33.

The vertical groove 35V has a depth at which a horizontal position of a connector 8C provided on the hard disk drive 8 matches a horizontal position of the connection connector 33C provided on the circuit board 33 when the guide pin 8P reaches a bottom of the vertical groove 35V. Further, the horizontal grooves 35H has a length at which the connector 8C provided on the hard disk drive 8 is connected to the connection connector 33C provided on the circuit board 33 when the guide pins 8P move to the innermost portions of the horizontal grooves 35H.

In the meantime, in each of the two moving rails 32, guide pin driving grooves 36 are formed at the same interval as the guiding grooves 35. Each of the guide pin driving grooves 36 includes an inclined part 36S at a side close to the circuit board 33 and a vertical part 36V at a side distant from the circuit board 33. When the moving rails 32 are slidably fitted between slide guides 31G provided in the fixed rails 31, any of the inclined parts 36S and the vertical parts 36V are overlaid with the guiding groove 35 while the moving rails 32 slide.

In addition, the hard disk drive attaching/detaching mechanism 30 is provided with a manipulating lever 34 which is a moving rail driving member configured to move the moving rails 32 with respect to the fixed rails 31. The manipulating lever 34 has a substantially U shape formed by two long rods 34A, two short rods 34B, and one interconnecting rod 34C. The long rods 34A have a length which is substantially equal to that of the fixed rails 31, the short rods 34B are connected to one ends of the long rods 34A which are close to the circuit board 33 at a predetermined angle, and the interconnecting rod 34C connects the other ends of the two long rods 34A. Each of the connection parts of the long rods 34A and the short rods 34B has a shaft hole 34H so that the connection parts of the long rods 34A and the short rods 34B are rotatably connected to the ends of the fixed rails 31 which are close to the circuit board 33 by pins 37 which penetrate the shaft holes 34H. Further, a long hole 34L is formed at a free end of each short rod 34B so that the pins 38 which penetrate the shaft holes 32H formed at the ends of the moving rails 32 which are close to the circuit board 33 are inserted into the long holes 34L.

In a state where the manipulating lever 34 is connected to the fixed rails 31 and the moving rails 32, when the long rods 34A of the manipulating lever 34 rotates around the fixed rails 31, the moving rails 32 move with respect to the fixed rails 31 by the short rods 34B. Further, in a state where the hard disk drive 8 is mounted in the hard disk drive attaching/detaching mechanism 30, the interconnecting rod 34C moves to a position of the other ends of the fixed rails 31 so that the manipulating lever 34 is closed. FIG. 8B illustrates a state where the hard disk drive 8 is not mounted in the hard disk drive attaching/detaching mechanism 30 which is provided in the rack mount server device 10 of the first embodiment of the present disclosure illustrated in FIG. 7B and represents a moving range of the manipulating lever 34.

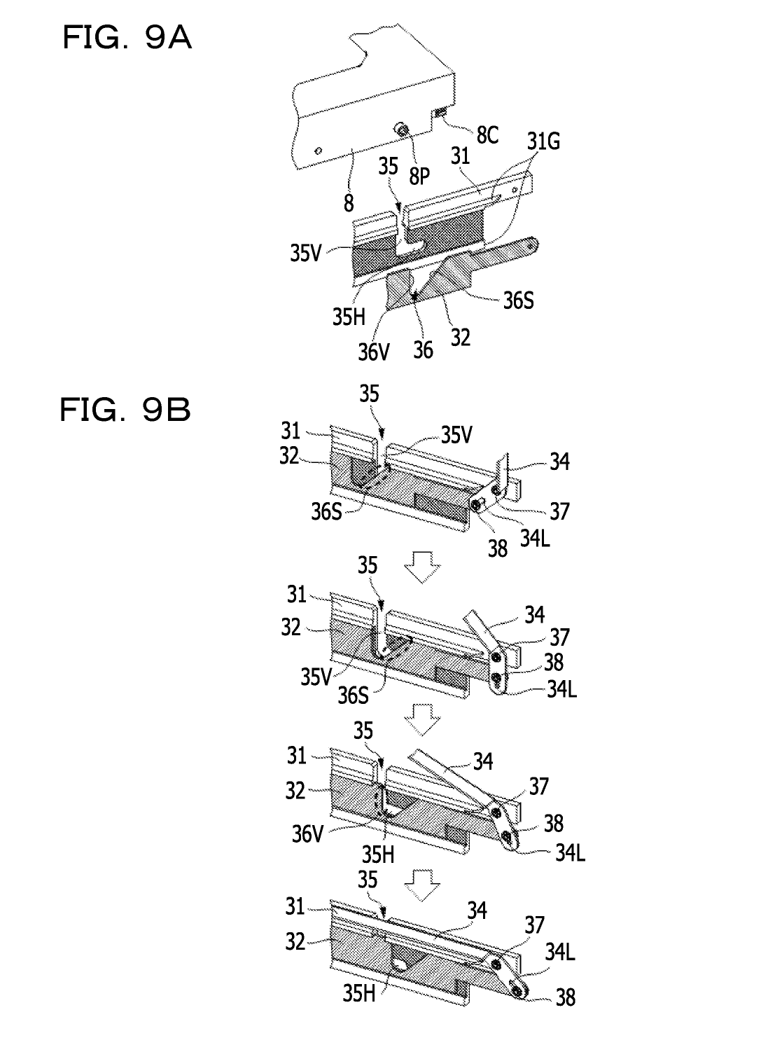

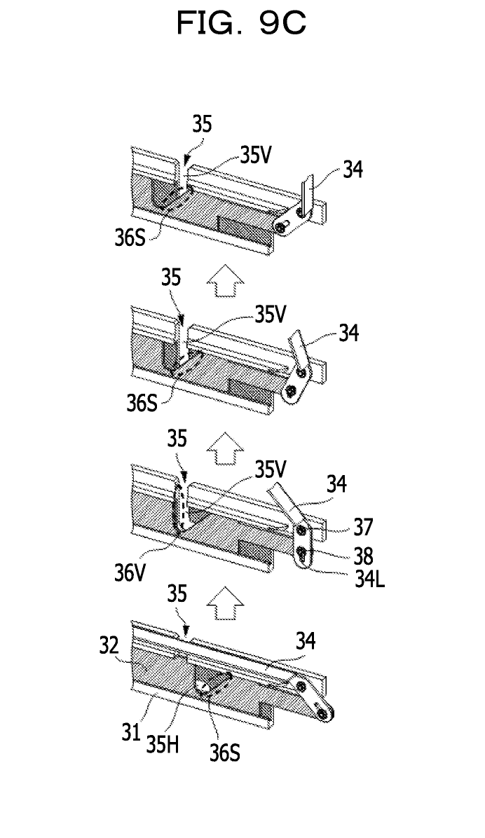

FIG. 9A illustrates a relationship between the guide pin 8P which is provided to protrude from the hard disk drive 8 and the fixed rail 31 and the moving rail 32 of the hard disk drive attaching/detaching mechanism 30 provided in the rack mount server device 10. The moving rail 32 is inserted between slide guides 31G which are provided on the fixed rail 31. When the hard disk drive 8 is attached to the hard disk drive attaching/detaching mechanism 30, the guide pin 8P is inserted in the guiding groove 35 formed in the fixed rail 31.

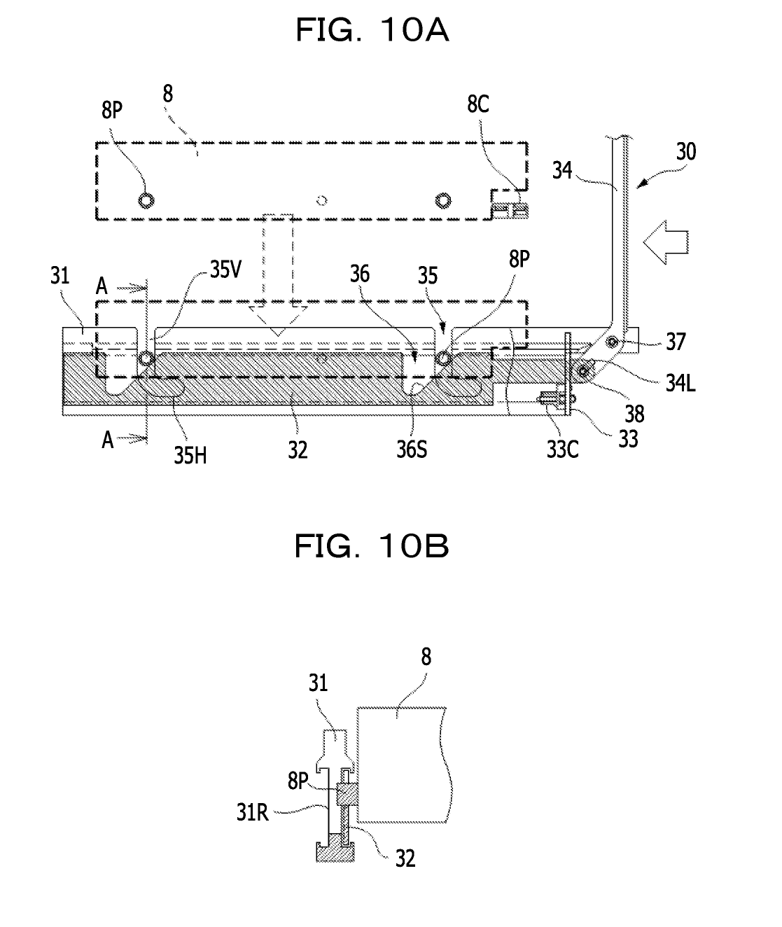

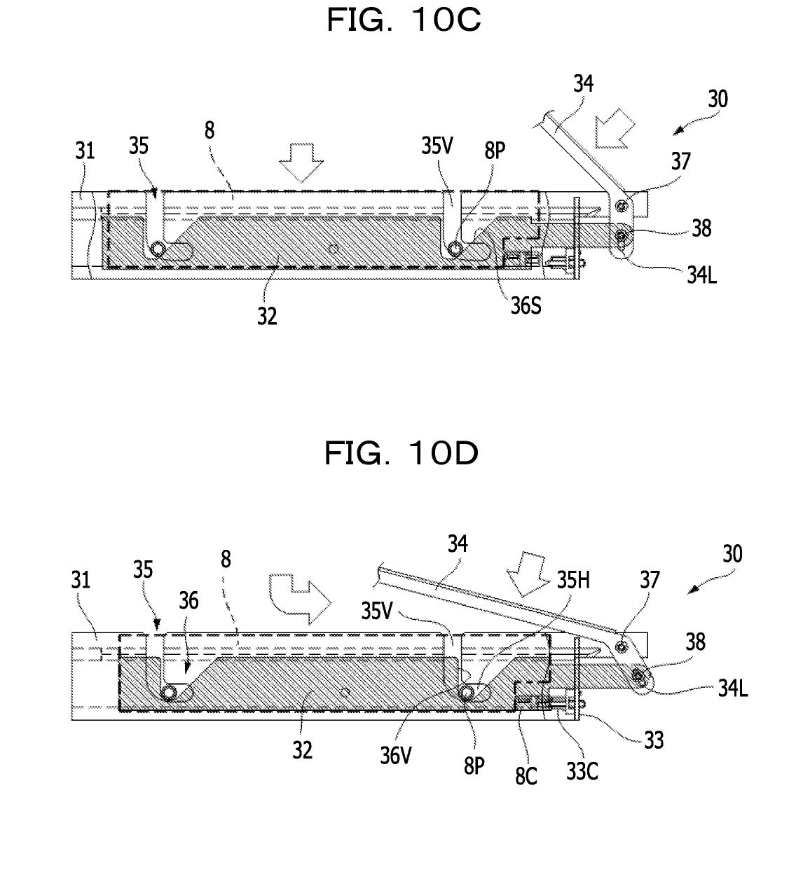

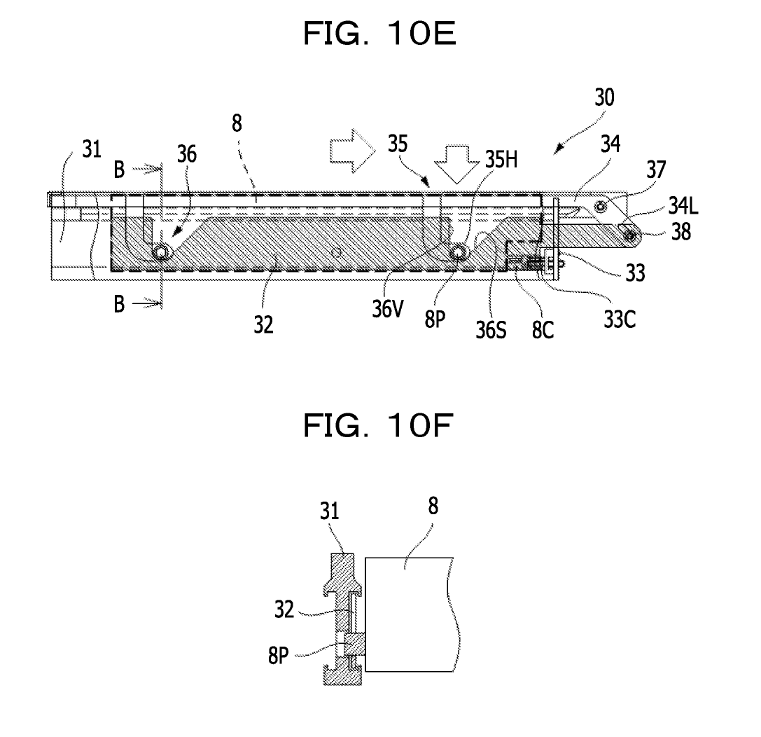

Here, an operation of the hard disk drive attaching/detaching mechanism 30 when the hard disk drive 8 is mounted in the hard disk drive attaching/detaching mechanism 30 will be described with reference to FIG. 9B, and FIGS. 10A to 10F. When the hard disk drive 8 is not mounted in the hard disk drive attaching/detaching mechanism 30, as illustrated in drawings at the top of FIGS. 10A and 9B, the manipulating lever 34 is in an erected state (an opened state) from the fixed rail 31. The moving rail 32 moves to a position which is the most distant from the circuit board 33. In this state, the inclined part 36S of the guide pin driving groove 36 is overlaid with the vertical groove 35V of the guiding groove 35.

When the hard disk drive 8 is mounted in the hard disk drive attaching/detaching mechanism 30 so that the guide pin 8P is inserted into the vertical groove 35V, the guide pin 8P stops by being in contact with the inclined part 36S of the guide pin driving groove 36 in the vertical groove 35V as illustrated in FIGS. 10A and 10B. FIG. 10B illustrates a cross-section taken along the line A-A of FIG. 10A. In this state, when the moving rail 32 moves to the circuit board 33 by reclining and rotating the manipulating lever 34, the inclined part 36S lowers the guide pin 8P in the vertical groove 35V while maintaining the guide pin 8P in a state where the inclined part 36S illustrated in FIG. 10A is overlaid with the vertical groove 35V.

When the manipulating lever 34 further rotates, the guide pin 8P moves to the bottom portion of the vertical groove 35V to be in a state illustrated in FIG. 10C. This state is a state where the inclined part 36S is overlaid with the horizontal groove 35H as illustrated in a second view of FIG. 9B. When the manipulating lever 34 further rotates in the state illustrated in FIG. 10C, as illustrated in a third view of FIG. 9B, the vertical part 36V of the guide pin driving groove 36 moves into the vertical groove 35V. Thereafter, as illustrated in FIG. 10D, the vertical part 36V of the guide pin driving groove 36 presses the guide pin 8P to be moved toward the circuit board 33 in the horizontal groove 35H of the guiding groove 35. Further, while the guide pin 8P moves toward the circuit board 33 in the horizontal groove 35H of the guiding groove 35, the connector 8C of the hard disk drive 8 is connected to the connection connector 33C in the circuit board 33.

When the manipulating lever 34 rotates to be overlaid with the fixed rail 31, as illustrated in a drawing at the bottom of FIG. 9B, the inclined part 36S of the guide pin driving groove 36 is not overlaid with the horizontal groove 35H. Further, in this state, the guide pin 8P is fixed to be interposed between the vertical part 36V of the guide pin driving groove 36 and an end of the horizontal groove 35H of the guiding groove 35. In this state, the connector 8C of the hard disk drive 8 is connected with the connection connector 33C provided on the circuit board 33. FIG. 10F illustrates a state taken along the line B-B of FIG. 10E.

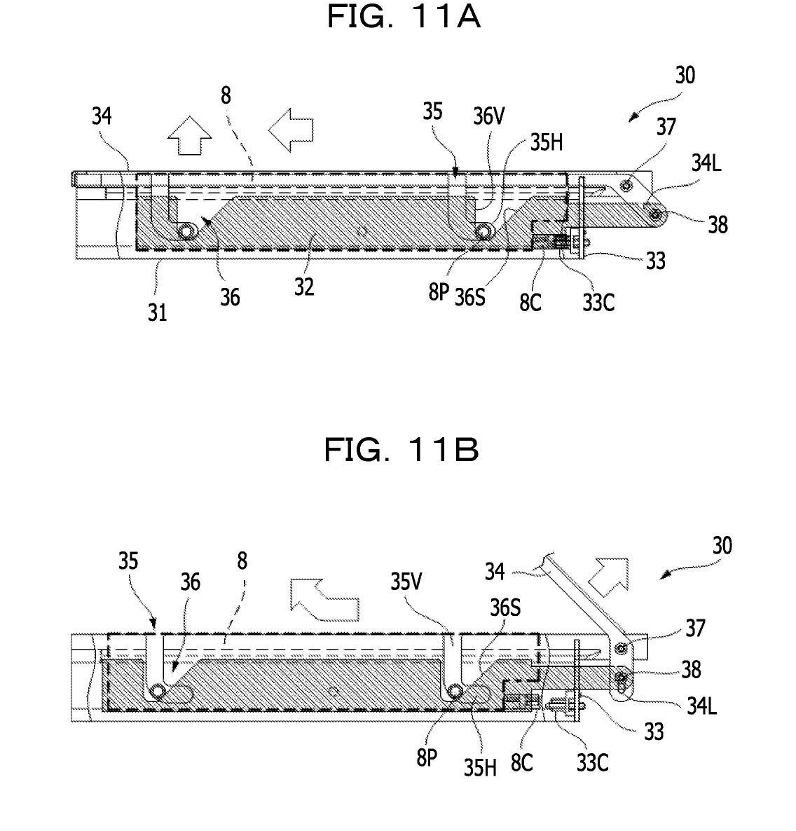

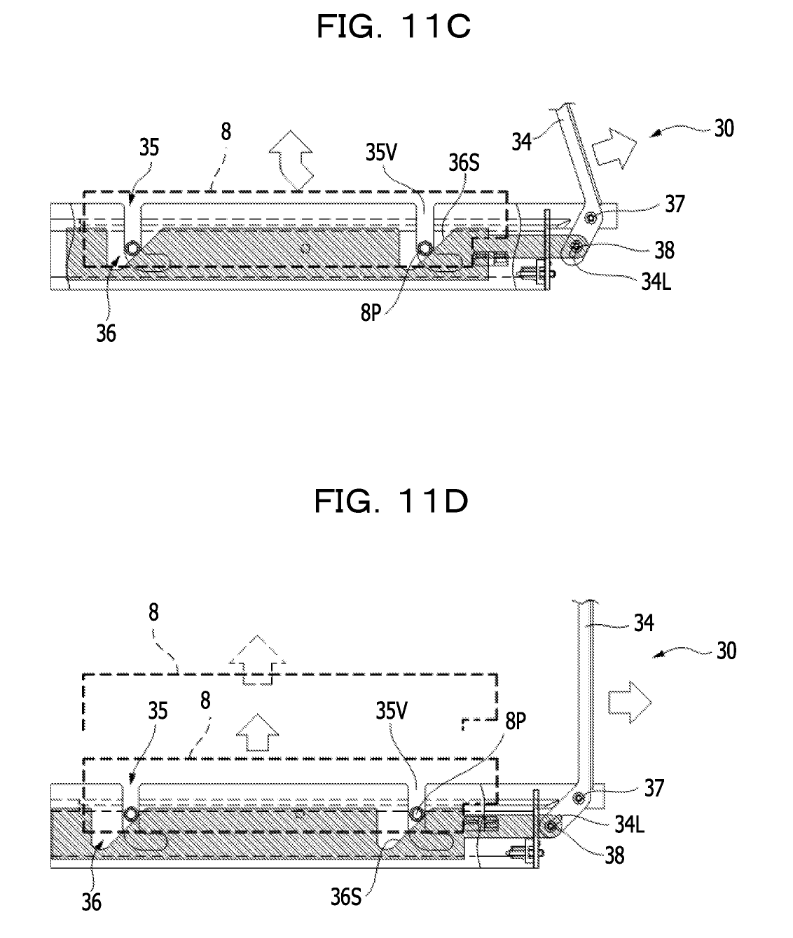

Next, an operation of the hard disk drive attaching/detaching mechanism 30 when the hard disk drive 8 is removed from the hard disk drive attaching/detaching mechanism 30 will be described with reference to FIGS. 9C, and 11A to 11F. A state of FIG. 11A is the same as the state illustrated in FIG. 10E. In this state, when the manipulating lever 34 is lifted, the inclined part 36S of the guide pin driving groove 36 is in contact with the guide pin 8P to press the guide pin 8P, as illustrated in the lowermost drawing of FIG. 9C.

When the manipulating lever 34 is lifted, as illustrated in FIG. 11B, the guide pin 8P is pressed by the inclined part 36S of the guide pin driving groove 36 to be moved in the horizontal groove 35H of the guiding groove 35 and then is in contact with the vertical groove 35V of the guiding groove 35 illustrated in a second drawing from the bottom of FIG. 9C so that the horizontal movement stops. Further, while the guide pin 8P moves in the horizontal groove 35H of the guiding groove 35, the connector 8C of the hard disk drive 8 is removed from the connection connector 33C in the circuit board 33. When the manipulating lever 34 is further lifted, the guide pin 8P is pressed by the inclined part 36S illustrated in the second drawing from the top of FIG. 9C to be elevated in the vertical groove 35V of the guiding groove 35 in this time. This state is illustrated in FIG. 11C.

When the manipulating lever 34 is erected to be in a vertical state with respect to the fixed rail 31, the manipulating lever 34 does not rotate any more so that the guide pin 8P is elevated in the vertical groove 35V of the guiding groove 35 to a position illustrated in FIG. 11D. In this case, the guide pin 8P is maintained on the inclined part 36S of the guide pin driving groove 36 illustrated in the first drawing from the top of FIG. 9C. When the guide pin 8P is elevated to the position illustrated in FIG. 11D, an upper portion of the hard disk drive 8 is exposed from the hard disk drive attaching/detaching mechanism 30. Therefore, the hard disk drive may be separated from the hard disk drive attaching/detaching mechanism 30 by grasping the exposed portion and raising the hard disk drive 8.

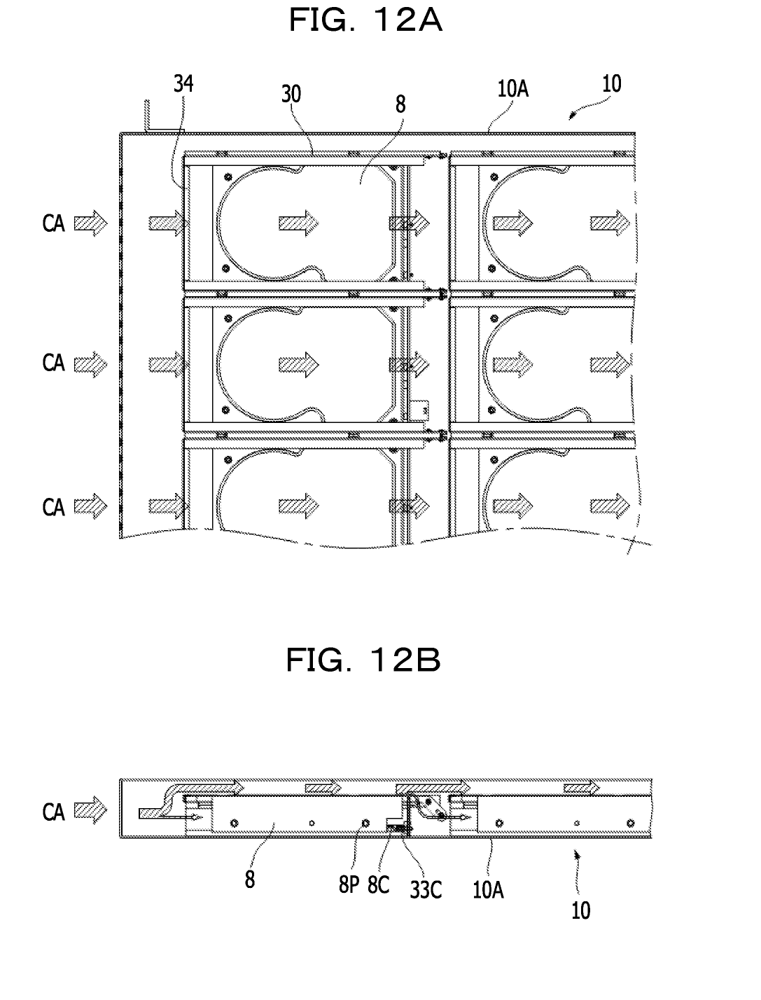

FIG. 12A illustrates flow of cooling air CA which flows in the housing 10A in the rack mount server device 10 according to the first embodiment which includes the hard disk drive attaching/detaching mechanism 30 of the present disclosure illustrated in FIG. 7B. Further, FIG. 12B is a side view illustrating the flow of the cooling air CA in the housing 10A of the rack mount server device 10 illustrated in FIG. 12A, as seen from a side. When the hard disk drive attaching/detaching mechanism 30 is used, there is no superfluous space between the hard disk drives 8. Further, a mechanism which blocks the flow of the cooling air CA is not necessary in the hard disk drive 8 itself. Therefore, lots of the cooling air CA flows onto a surface of the hard disk drive 8 so that the heated part may be efficiently cooled down.

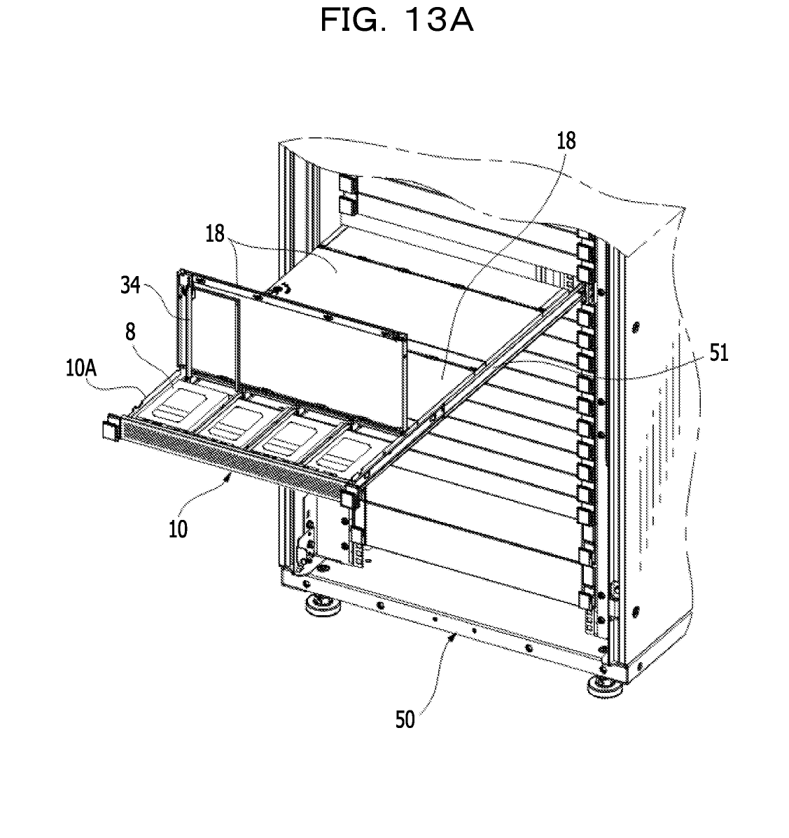

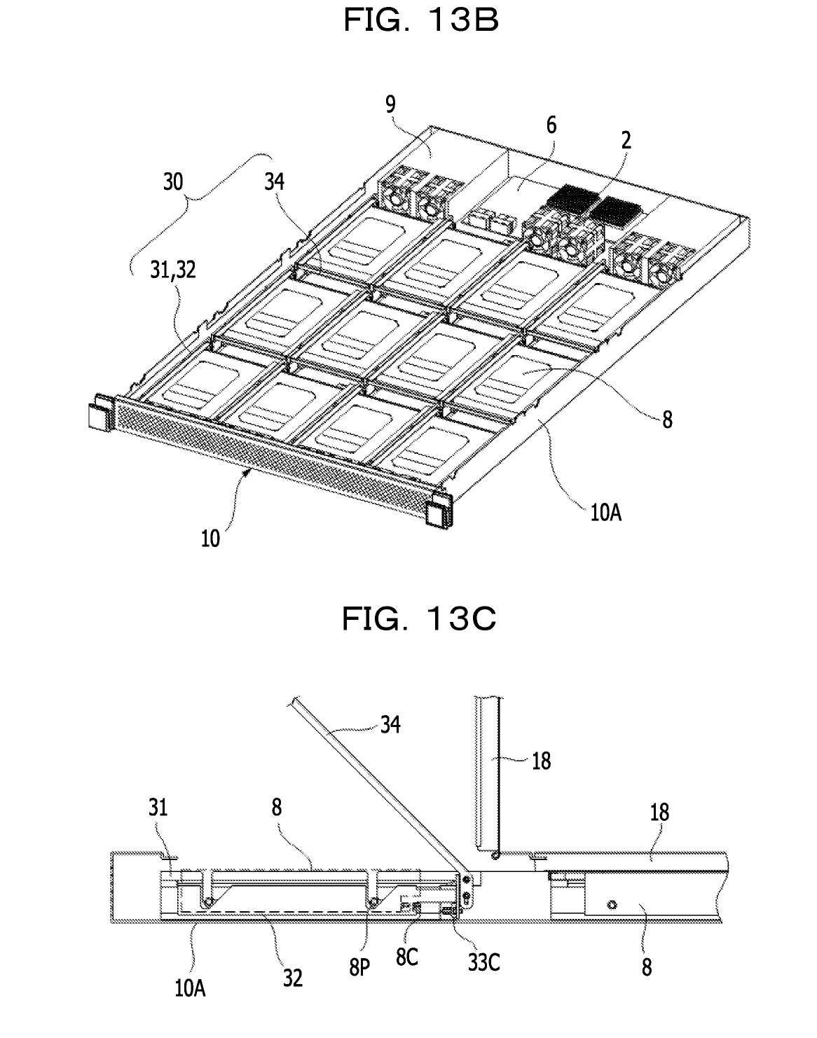

FIG. 13A illustrates a state where the rack mount server device 10 illustrated in FIG. 7B is ejected from a server mounting rack 50 which is an information processing apparatus. A slide rail 51 which ejects the rack mount server device 10 from the server mounting rack 50 is provided at a side of the housing 10A of the rack mount server device 10. In the rack mount server device 10, as illustrated in FIG. 13B, a mother board 6, a power unit 9, and a cooling fan 2 which configure main functions of the server are mounted. Further, in the rack mount server device 10, the hard disk drive attaching/detaching mechanisms 30 each of which includes the fixed rails 31, the moving rails 32, and the manipulating lever 34 is provided so as to attachable mount the hard disk drives 8.

In the hard disk drive attaching/detaching mechanism 30 of the rack mount server device 10, as illustrated in FIG. 13C, a hard disk 8 with the guide pins provided at both sides is mounted. Further, the maintenance cover 18 which partially opens and closes only the hard disk drive 8 even while the device is activated is provided at an upper portion of the mounting unit of the hard disk 8. In the meantime, the maintenance cover 18 illustrated in FIGS. 13A and 13C is not illustrated in FIG. 13B.

According to the present disclosure, a hard disk drive is mounted by using the hard disk drive attaching/detaching mechanism so that there is no need to provide an inserting/removing mechanism in the hard disk drive and a working space may be restricted to the minimum. As a result, the hard disk drive may be easily attached and detached. Further, a mounting density of the hard disk drives is improved and component costs may be reduced. Furthermore, as the mounting density is improved, a cooling path is optimized, which may improve a cooling performance.

In the meantime, in the first embodiment, even though the rack mount server device 10 in which the hard disk drive attaching/detaching mechanism 30 is mounted has been described, the hard disk drive attaching/detaching mechanism 30 may be mounted in a storage device in which a CPU is not mounted.

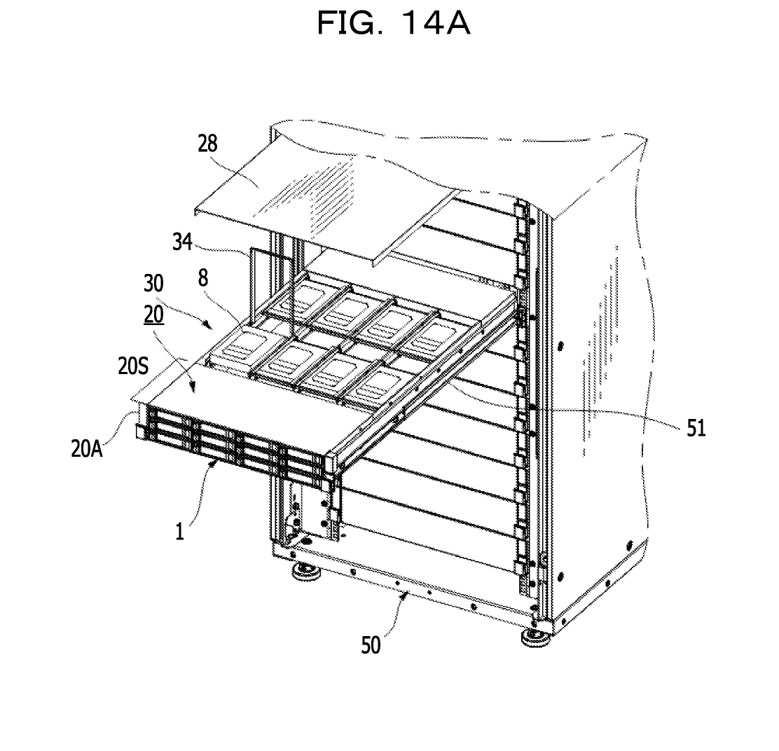

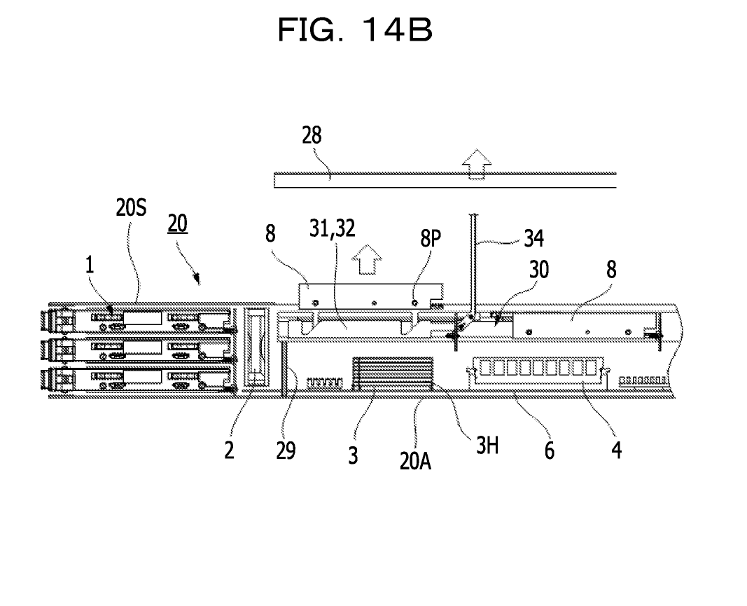

FIG. 14A illustrates a state where a rack mount server device 20 of a second embodiment of the present disclosure which is mounted in a server mounting rack 50 is extracted from the server mounting rack 50 using a slide rail 51 which is attached to a housing 20A. The height of the rack mount server device 10 of the first embodiment has a minimum size (1 U size). To the contrary, the rack mount server device 20 of the second embodiment has a higher height (for example, 2 U size) than the rack mount server device 10 of the first embodiment, which is different from the rack mount server device 10 of the first embodiment. Because the rack mount server device 20 of the second embodiment has a 2 U size height, three stages of hard disk drives 1 are piled up on a front shelf 20S to be overlaid with each other in a height direction of the housing 20A. The hard disk drive 1 which is mounted on the front shelf 20S of the rack mount server device 20 may be attached to/detached from a front side of the front shelf 20S so that no guide pin is provided at both sides of the hard disk drive 1.

FIG. 14B is the rack mount server device 20 illustrated in FIG. 14A when viewed from a side. The front shelf 20S on which the hard disk drives 1 which may be attached to and detached from the front side are mounted is provided in the rack mount server device 20. The mother board 6 which configures a main function of the server, a cooling fan 2, a CPU 3 including a heat sink 3H, a memory 4, and an extension PCI board (not illustrated) are disposed at a rear side of the front shelf 20S. In the rack mount server device 20 having a 2 U size height, as illustrated above, since the CPU 3 including the heat sink 3H or the memory 4 is short, there is an unused area above the mother board 6.

Therefore, in the second embodiment, the hard disk drive attaching/detaching mechanism 30 which is provided in the rack mount server device 10 of the first embodiment is attached to a housing 20A using a spacer 29 so as not to interfere with the mother board 6. A hard disk drive 8 including guide pins 8P is mounted in the hard disk drive attaching/detaching mechanism 30 and an upper cover 28, which may be removed in a state where the device is activated, is provided in the upper portion of the hard disk drive attaching/detaching mechanism 30.

In a general rack mount server device having a 2 U size height, an unused area is created above the CPU or the memory due to a difference of heights of components to be mounted in a portion where the main function of the mother board is mounted and a portion where, for example, the extension PCI board, the cooling fan, and the hard disk are mounted. In the meantime, in the rack mount server device 20 of the second embodiment of the present disclosure, the hard disk drive attaching/detaching mechanism 30 is provided in the unused area to mount the hard disk drive 8 so that the number of mounted hard disk drives 8 is increased. Further, the hard disk drive attaching/detaching mechanism 30 is mainly configured by the fixed rails 31, the moving rails 32, and the manipulating lever 34 and when the hard disk drive 8 is removed, a bottom portion is opened so that maintenance/extension workability of the CPU 3 or the memory 4 on the mother board 6 is not damaged as much as possible. As described above, in the rack mount server device 20 of the second embodiment, the hard disk drive 8 is mounted in a location which is originally considered as a dead space so that the unused area is efficiently used, which may result in high density mounting.

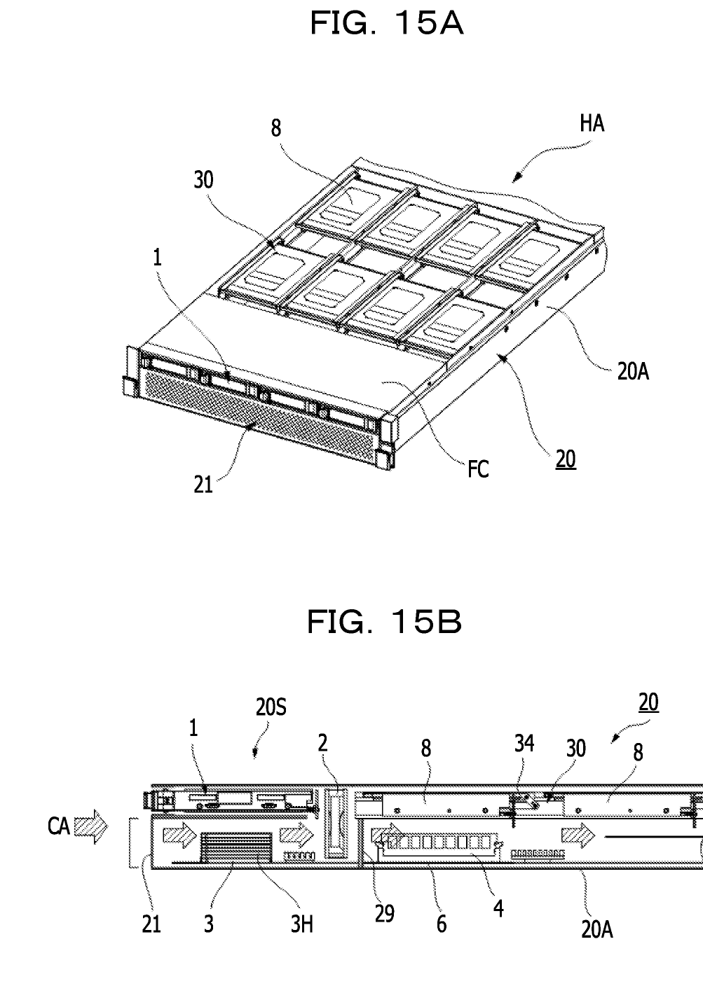

FIG. 15A illustrates a rack mount server device 20 having a 2 U size height of a modified embodiment of the second embodiment which may be mounted in a server mounting rack. Further, FIG. 15B illustrates an internal structure of the rack mount server device 20 illustrated in FIG. 15A and a state of cooling air CA which flows therein. In this modified embodiment, a mother board 6 is disposed in a part (lower portion) of the front shelf 20S in which the hard disk drive 1, which is attachable to the front surface, is mounted and the CPU 3 is mounted thereon. An intake port 21 is provided on a front surface of the rack mount server device 20 so that a larger amount of cooling air CA reaches the CPU 3.

In the meantime, a hard disk drive 1 which may not be mounted on the front shelf 20S by mounting the CPU 3 on the front surface of the rack mount server device 20 is changed into a hard disk drive 8 having a guide pin 8P with the same storage capacity as the hard disk drive 1. The changed hard disk drive 8 is mounted using the hard disk drive attaching/detaching mechanism 30 in a space above the mother board 6 using a spacer 29, similarly to the second embodiment. In the mother board 6 positioned below the hard disk drive attaching/detaching mechanism 30, a memory 4 may be mounted.

Generally, a large amount of hard disk drives are mounted in the rack mount server device, the hard disk drives are disposed on the front surface of the device in which the intake port is disposed. Therefore, the hard disk drive serves as an obstacle and an amount of cooling air which flows into the rack mount server device is reduced so that when a CPU for a server having a high heat generation amount is cooled down, cooling efficiency by the cooling air is lowered.

However, the hard disk drives disposed on the front surface of the rack mount server device are mounted in the device so that the CPU which needs to be cooled down most may be disposed in a location having the best cooling efficiency by the cooling air while maintaining the number of mounted hard disk drives. Accordingly, the cooling efficiency of the CPU may be significantly improved and the capacity of the cooling fan may be restricted so that the power may be saved.

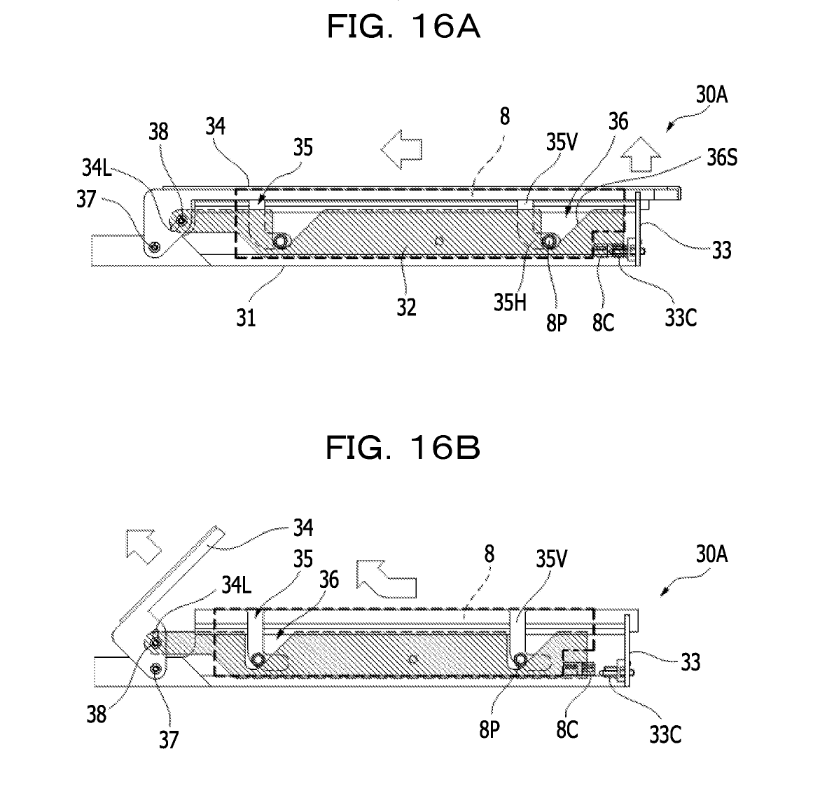

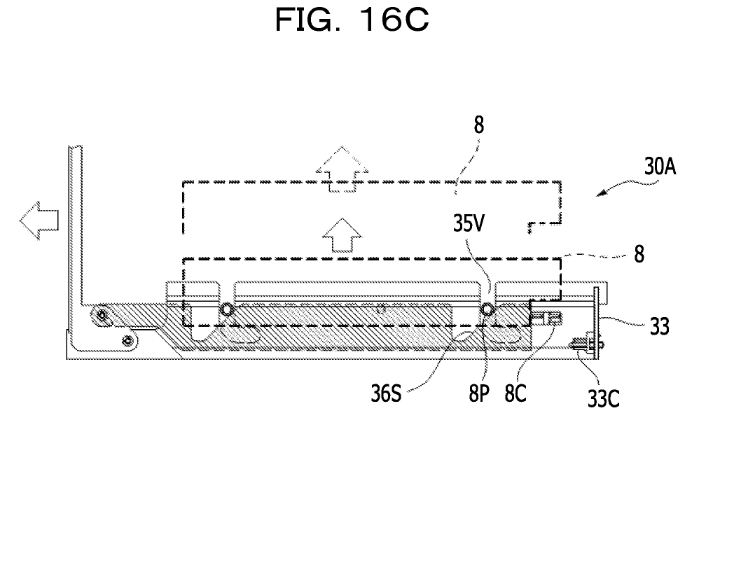

FIG. 16A illustrates a hard disk drive attaching/detaching mechanism 30A having another structure which is mounted in the rack mount server device 10 of the first embodiment of the present disclosure. In the hard disk drive attaching/detaching mechanism 30 having a structure illustrated in FIGS. 8A and 8B, a rotation base of the manipulating lever 34 is provided at a side which is close to the circuit board 33 and the interconnecting rod 34C is provided at an end of the fixed rail 31 which is away from the circuit board 33. In contrast, in the hard disk drive attaching/detaching mechanism 30A illustrated in FIG. 16A, the rotation base of the manipulating lever 34 is provided at a side which is away from the circuit board 33 and the interconnecting rod 34C is provided at an end of the fixed rail 31 which is close to the circuit board 33. Structures of the fixed rail 31 and the moving rail 32 in the hard disk drive attaching/detaching mechanism 30A are the same as the structures of the fixed rail 31 and the moving rail 32 in the hard disk drive attaching/detaching mechanism 30.

Accordingly, the operations of the hard disk drive attaching/detaching mechanism 30A are totally the same as the operations of the hard disk drive attaching/detaching mechanism 30 except for a direction of lifting the manipulating lever 34. A state of FIG. 16A corresponds to a state of FIG. 11A, a state of FIG. 16B corresponds to a state of FIG. 11B, and a state of FIG. 16C corresponds to a state of FIG. 11D. Accordingly, like components are denoted by like reference numerals and descriptions of the operations thereof will be omitted.

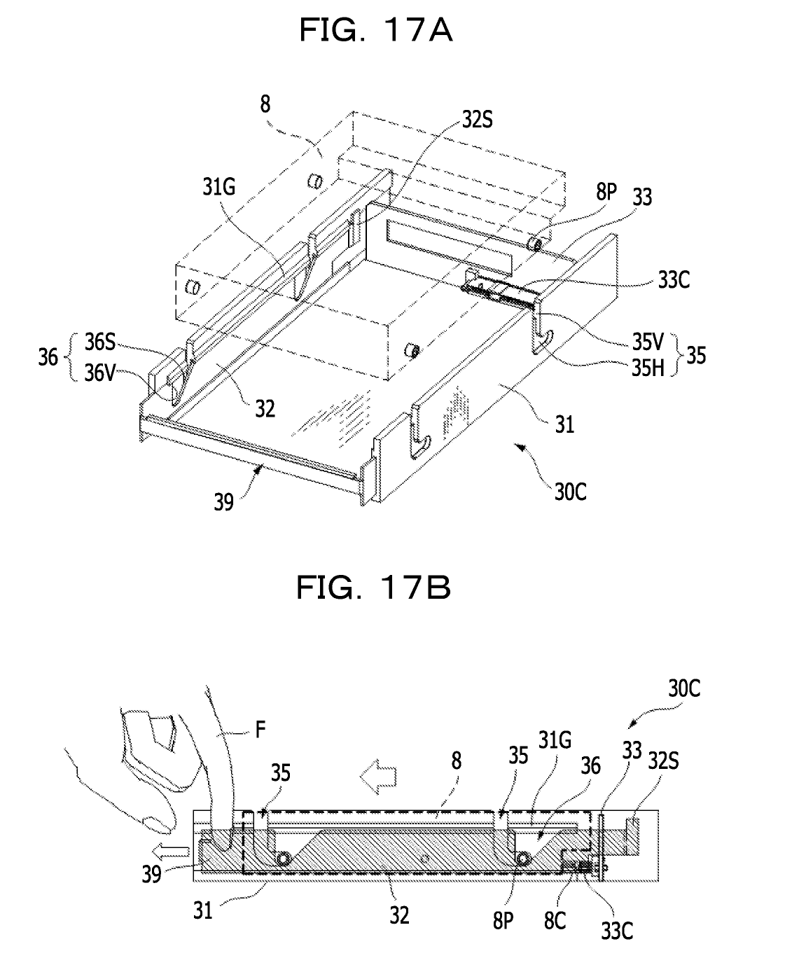

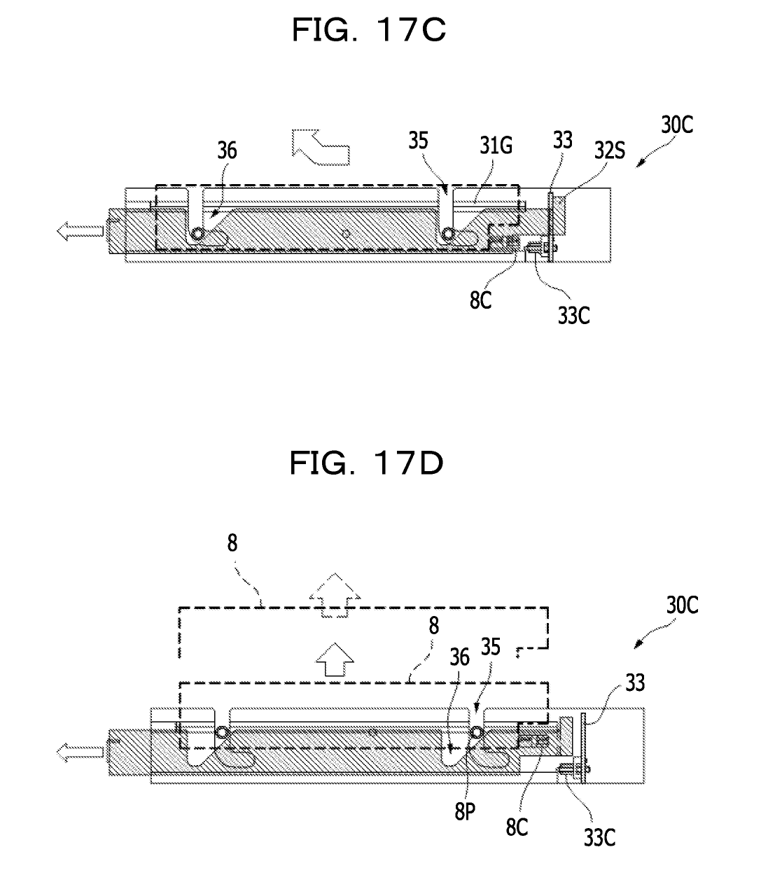

FIG. 17A illustrates a hard disk drive attaching/detaching mechanism 30C having another structure which is provided in a rack mount server device of the present disclosure. The hard disk drive attaching/detaching mechanism 30C does not have a manipulating lever but includes a manipulating rod 39 of which both ends are connected to an end of the moving rail 32 which is away from the circuit board 33. In the hard disk drive attaching/detaching mechanisms 30 and 30A, the manipulating lever 34 rotates with respect to the fixed rail 31 to move the moving rail 32. To the contrary, in the hard disk drive attaching/detaching mechanism 30C of this embodiment, the moving rail 32 moves by pulling or pressing the manipulating rod 39 from the outside. Therefore, a stopper 32S which determines a maximum extraction position of the moving rail 32 is provided at an end of the moving rail which is close to the circuit board 33. The moving rail 32 may be extracted to a position where the stopper 32S is in contact with an end of the slide guide 31G which is provided in the fixed rail 31.

FIG. 17B illustrates a state where a finger F is crooked around the manipulating rod 39 of the hard disk drive attaching/detaching mechanism 30C to extract the moving rail 32 in which the states of the hard disk drive 8, the fixed rail 31, and the moving rail 32 are the same as the states illustrated in FIG. 11A. FIG. 17C illustrates a state where the manipulating rod 39 is further pulled out from the state of FIG. 17B in which the states of the hard disk drive 8, the fixed rail 31, and the moving rail 32 are the same as the states illustrated in FIG. 11B. FIG. 17D illustrates a state where the manipulating rod 39 is extracted to the maximum extracting position from the state of FIG. 17C in which the states of the hard disk drive 8, the fixed rail 31, and the moving rail 32 are the same as the states illustrated in FIG. 11D. A member which moves the moving rail with respect to the fixed rail in the hard disk drive attaching/detaching mechanism is not limited to the manipulating lever or the manipulating rod.

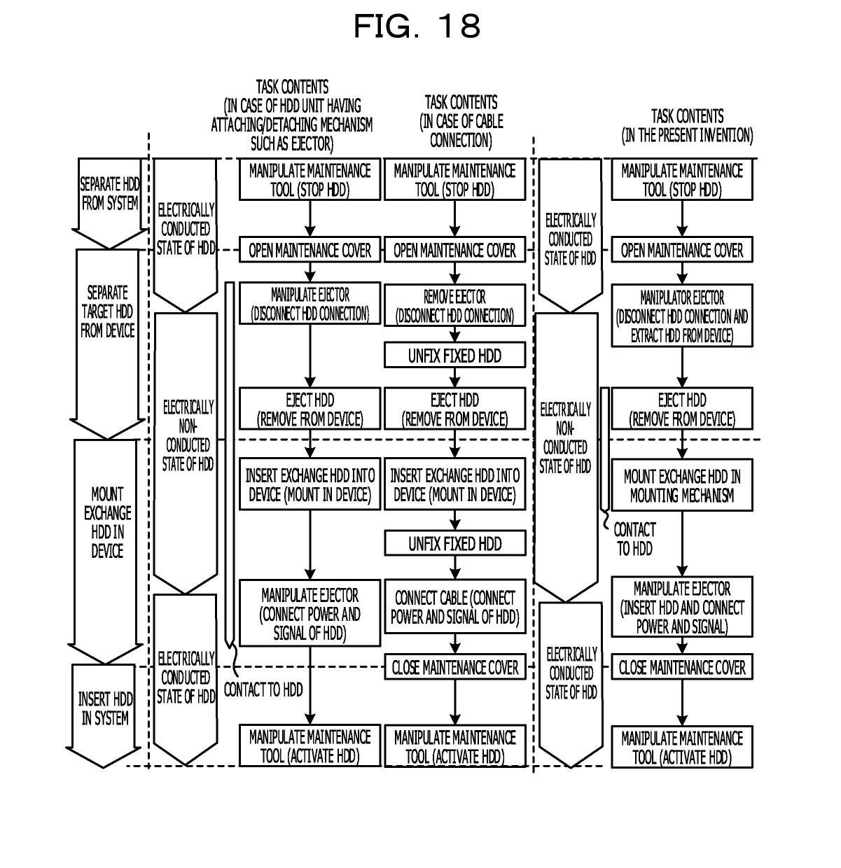

FIG. 18 is a flowchart illustrating an exchange procedure when one hard disk drive is actively exchanged from a rack mount server device including a hard disk drive attaching/detaching mechanism of the present disclosure which is mounted in the server mounting rack by comparing with an exchange procedure in a comparative technology. In FIG. 18, the hard disk drive is abbreviated as an HDD.

Generally, when the hard disk drive is mounted in the rack mount server device, an operator is required to perform a task while being in contact with the hard disk drive which is in an electrically conducted state. However, in a rack mount server device including the hard disk drive attaching/detaching mechanism of the present disclosure, an electric connection and disconnection may be performed without being in contact with the hard disk drive. Accordingly, a cover which protects the single body of the hard disk for protection against danger or prevention of malfunction or other mechanism components are not required. As a result, the mounting density may be enhanced and the cost may be reduced due to the reduced number of unnecessary components. Further, a cooling path may be simplified by removing the unnecessary components or space for cooling so that the hard disk drive to be cooled down may be efficiently cooled down, which may result in improvement of cooling performance.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A hard disk drive mounting device comprising:
a housing;
a mounting area provided in the housing and configured to mount a plurality of hard disk drives;
a first hard disk drive provided with a guide pin protruding on both side surfaces thereof; and
a mechanism configured to attach the first hard disk drive to the mounting area, and configured to detach the first hard disk drive from the mounting area, the mechanism including:
a fixed rail including a guiding groove configured to receive the guide pin, and
a moving rail positioned adjacent to the fixed rail and configured to move the guide pin inserted into the guiding groove by a driving groove,
wherein, when the moving rail moves to one end of the fixed rail in a state where the guide pin is inserted into the guiding groove, the first hard disk drive is mounted in a mounting part, and
when the moving rail moves to the other end of the fixed rail in a state where the first hard disk drive is mounted in the mounting part, the hard disk drive is ejected from the mounting part.

2. The hard disk drive mounting device according to claim 1, further comprising:
a second hard disk drive which includes a fitting on a front surface and does not have a guide pin;
a first mounting area formed in the housing configured to mount the first hard disk drive therein; and
a second mounting area formed in the housing configured to mount the second hard disk drive therein,
wherein the second mounting area is formed at a front surface side of the housing,
the first mounting area is formed to be closer to a rear surface side of the housing than the second mounting area, and
the mechanism is provided in the first mounting area.

3. The hard disk drive mounting device according to claim 1, wherein two fixed rails are disposed in parallel to each other,
a substrate, which is provided with a first connector coupled to the first hard disk drive, is provided between one ends of the fixed rails,
the moving rail is configured to slide in the fixed rails away from or toward the substrate,
the guiding groove includes a vertical groove configured to receive the guide pin when the first hard disk drive is mounted and a horizontal groove configured to move the guide pin in the vertical groove to the substrate, and
the driving groove includes an inclined part at a side which is positioned close to the substrate and a vertical part at a side which is positioned away from the substrate, the driving groove being configured to cause the inclined part or the vertical part to be in contact with the guide pin to move the guide pin in the guiding groove when the moving rail slides.

4. The hard disk drive mounting device according to claim 3, wherein the vertical groove has a depth such that a second connector provided over the hard disk drive matches the first connector provided over the substrate in horizontal position when the guide pin reaches a bottom of the vertical groove, and
the horizontal groove has a length such that the second connector provided over the first hard disk drive is coupled to the first connector when the guide pin moves to the end of the horizontal groove.

5. The hard disk drive mounting device according to claim 3, wherein, when the moving rail is moved to a position which is closest to the substrate, an inclined part of the guide pin driving groove is positioned outside an end of a horizontal groove of the guiding groove,
when the moving rail is moved away from the substrate, the inclined part moves the guide pin toward the vertical groove in a state where the inclined part is overlaid with the horizontal groove, and the inclined part upwardly lifts the guide pin from the vertical groove in a state where the inclined part is overlaid with the vertical groove.

6. The hard disk drive mounting device according to claim 1, further comprising:
a control lever provided in the moving rail and configured to move the moving rail by applying an external force thereto.

7. The hard disk drive mounting device according to claim 6, wherein the control lever is a lever which includes two long rods, two short rods, and one interconnecting rod,
the long rods have a length which is substantially equal to that of the fixed rail, the short rods are bent and coupled to the long rod at substrate side ends of the two long rods, and the interconnecting rod couples the other side ends of the two long rods,
connection parts of the long rods and the short rods are pivotally supported at a substrate side end of the fixed rail,
free ends of the short rods are coupled to a substrate side end of the moving rail through a long hole, and
when the first hard disk drive is mounted in the mechanism, the interconnecting rod is in a position of the other end of the fixed rail and the lever is closed.

8. The hard disk drive mounting device according to claim 1, wherein one fixed rail is provided to be adjacent to the mechanism and the moving rails are disposed on both side surfaces of the fixed rail.

9. The hard disk drive mounting device according to claim 1, wherein two guide pins protrude on each of opposite side surfaces of the first hard disk drive at the same positions on the opposite side surfaces of the first hard disk drive,
two guiding grooves are formed in the fixed rail, and
two driving grooves are formed in the moving rail.

10. The hard disk drive mounting device according to claim 6, wherein the control lever includes two long rods, two short rods, and one interconnecting rod,
the long rods have a length which is substantially equal to that of the fixed rail, the short rods are bent and coupled to the long rod to at substrate side ends of the two long rods, and the interconnecting rod couples the other side ends of the two long rods,
free ends of the short rods are pivotally supported at an end of the fixed rail which is opposite to the substrate,
a vicinity of the connection parts of the short rods and the long rods is coupled to the end of the moving rail which is opposite to the substrate, through long holes, and
when the first hard disk drive is mounted in the mechanism, the interconnecting rod is positioned at the substrate side end of the fixed rail and the lever is closed.

11. The hard disk drive mounting device according to claim 6, wherein the control lever is a rod which couples ends of the moving rails which are opposite to the substrate,
stoppers configured to restrict a movement range of the moving rails is provided at the substrate side ends of the moving rails, and
when the first hard disk drive is mounted in the mechanism, the rod is positioned at the other side end of the fixed rail.

12. The hard disk drive mounting device according to claim 1, wherein, when the moving rail is moved to a position which is most distant from the substrate, an inclined part of the guide pin driving groove is overlaid with a vertical groove of the guiding groove,
when the moving rail is moved toward the substrate in a state where the first hard disk drive is mounted in the mechanism and the guide pin is inserted into the vertical groove, the inclined part lowers the guide pin in the vertical groove while maintaining the guide pin in a state where the inclined part is overlaid with the vertical groove, and the vertical part of the guide pin driving groove presses the guide pin to move the guide pin toward the substrate in the horizontal groove in a state where the inclined part is overlaid with the horizontal groove.

13. The hard disk drive mounting device according to claim 1, wherein the hard disk drive mounting device is a rack mount server device,
the mounting area of the first hard disk drive is disposed at the front surface side of the housing, and
at least a cooling fan, a circuit board, and a power unit are provided at a rear surface side of the housing.

14. The hard disk drive mounting device according to claim 13, wherein a plurality of mechanisms is provided to be arranged side by side in a horizontal direction and a depth direction in the mounting area of the first hard disk drive, and
a maintenance cover which covers the mechanism is provided over the mechanisms to be arranged side by side in the horizontal direction,

15. The hard disk drive mounting device according to claim 1, wherein the hard disk drive mounting device is a storage device and only a mounting area of the first hard disk drive is formed in the storage device.

16. An information processing apparatus, comprising:
a rack; and
a plurality of hard disk drive mounting devices which is piled up in the rack,
wherein the hard disk drive mounting devices include:
a housing;
a mounting area provided in the housing and configured to mount a plurality of hard disk drives;
a first hard disk drive provided with a guide pin protruding on both side surfaces thereof; and
a first mechanism configured to attach the first hard disk drive in a first hard disk drive mounting area of the mounting area, and to configured to detach the first hard disk drive from the first hard disk drive mounting area,
the first mechanism including:
a fixed rail including a guiding groove configured to receive the guide pin; and
a moving rail which is positioned adjacent to the fixed rail and configured to move the guide pin which is inserted in the guiding groove by a driving groove,
wherein, when the guide pin is inserted in the guiding groove, if the moving rail moves to one end of the fixed rail, the first hard disk drive is mounted in a mounting part, and
when the moving rail moves to the other end of the fixed rail, the first hard disk drive is ejected from the mounting part.

17. The information processing apparatus according to claim 16, further comprising:
a second hard disk drive which includes a second mechanism on a front surface and does not have a guide pin,
a first mounting area formed in the housing configured to mount the first hard disk therein; and
a second mounting area formed in the housing configured to mount the second hard disk drive therein,
wherein the second mounting area is formed at a front surface side of the housing,
the first mounting area is formed to be closer to a rear surface side of the housing than the second mounting area,
the first mechanism configured to attach the first hard disk drive to the first mounting area, and configured to detach the first hard disk drive from the first mounting area, and
the second mechanism configured to attach the second hard disk drive to the second hard disk drive mounting area, and to configured to detach the second hard disk drive from the second hard disk drive mounting area.
